(19) United States
(12) Patent Application Publication
(10) Pub. No.: US 2011/0120761 A1
(43) Pub. Date: May 26, 2011

(54) EPOXY RESIN COMPOSITIONS

(75) Inventor: Kenji KAWAI, Kawasaki-shi (JP)

(73) Assignee: AJINOMOTO CO. INC., Tokyo (JP)

(21) Appl. No.: 12/951,138

(22) Filed: Nov. 22, 2010

(30) Foreign Application Priority Data
Nov. 26, 2009 (JP) 268550/2009

(51) Int. Cl. H05K 1/03; C08L 63/00; B32B 3/30; B05D 5/12; B32B 37/00

(52) U.S. Cl. 174/258; 525/486; 524/541; 525/472; 525/418; 525/471; 525/461; 525/109; 428/141; 427/97.6; 156/280

(57) ABSTRACT

Epoxy resin compositions which comprise an epoxy resin (A), an active ester compound (B), and a triazine-containing cresol novolac resin (C), when cured and roughened, exhibit a roughed surface which has a high adhesion strength to a metal plated conductor, even though the roughness of the roughed surface is small, and provide an insulating layer which has a low coefficient of linear expansion and a low dielectric loss tangent.

### CROSS REFERENCES TO RELATED APPLICATIONS

This application claims priority to Japanese Patent Application No. 268550/2009, filed on Nov. 26, 2009, which is incorporated herein by reference in its entirety.

### BACKGROUND OF THE INVENTION

1. Field of the Invention

The present invention relates to specific epoxy resin compositions which can be used in formation of an insulation layer for multilayer printed wiring boards.

2. Discussion of the Background

In the multilayer printed wiring boards, the built-up layer has been multiplied, the microminiaturization and high-density assembly of wiring have been investigated, and further the insulating materials with low dielectric loss tangent have been required for reduction of transmission loss, with development of the miniaturization and high-performance in electronic devices in recent years.

In this situation, a wide variety of trials have been performed for solving these problems. For example, JP-A-2007-254709 discloses epoxy resin compositions which comprise an epoxy resin, a specific phenolic curing agent, phenolic resin and rubber particles, and JP-A-2007-254710 discloses epoxy resin compositions which comprise an epoxy resin, a specific phenolic curing agent and polyvinyl acetal resin. In the insulating layers formed with these compositions, however, there is no disclosure nor suggestion relating to any concept of low coefficient of linear expansion or low dielectric loss tangent, though the high peeling strength of an inductive layer formed by means of both of low roughness and metal plating has been attained.

### SUMMARY OF THE INVENTION

Accordingly, it is one object of the present invention to provide novel epoxy resin compositions.

It is another object of the present invention to provide novel epoxy resin compositions, wherein the roughed surface generated from the surface of the cured product of said epoxy resin composition by a roughing treatment has a high adhesion strength to a metal plated conductor, even though the roughness of the roughed surface is small, and the resulting insulating layer has a low coefficient of linear expansion and a low dielectric loss tangent.

These and other objects, which will become apparent during the following detailed description, have been achieved by the inventors' discovery that specific epoxy resin compositions which comprise an epoxy resin, an active ester compound, and a triazine-containing cresol novolac resin are effective for achieving these objects.

Thus, the invention provides:

(1) An epoxy resin composition which comprises an epoxy resin (A), an active ester compound (B), and a triazine-containing cresol novolac resin (C).

(2) An epoxy resin composition as described in the above item (1), wherein the ratio of an epoxy group of the component (A) to reactive groups of the components (B) and (C) is from 1:0.3 to 1:1.5, and the ratio by weight of nonvolatile components in the component (B) to the component (C) is from 1:0.05 to 1:1.5.

(3) An epoxy resin composition as described in the above item (1) or (2), which further comprises an inorganic filler (D).

(4) An epoxy resin composition as described in any of the above items (1) to (3), which further comprises a curing accelerator (E).

(5) An epoxy resin composition as described in any of the above items (1) to (4), which further comprises as a component (F) one or more species of polymer resins selected from polyvinyl acetal resin, phenoxy resin, polyimide resin, polyamide-imide resin, polyether imide resin, polysulfone resin, polyether sulfone resin, polyphenylene ether resin, polycarbonate resin, polyether ether ketone resin, and polyester resin.

(6) An epoxy resin composition as described in the above items (1) to (5), which further comprises rubber particles (G).

(7) An epoxy resin composition as described in any of the above items (1) to (6), wherein the peeling strength is 0.3 kgf/cm to 1.0 kgf/cm; the arithmetic mean roughness is 50 nm to 220 nm; the dielectric loss tangent is 0.001 to 0.010; and the average coefficient of linear expansion is 4 ppm to 24 ppm.

(8) An adhesive film, which is characterized in that the epoxy resin composition as described in any of the above items (1) to (7) is layered over a support film.

(9) A prepreg, which is characterized in that a sheet fiber base material comprising fiber is impregnated with the epoxy resin composition as described in any of the above items (1) to (8).

(10) A multilayer printed wiring board, which is characterized in that an insulating layer is formed with a cured product of the epoxy resin composition as described in the above item (8) or (9).

(11) A process for producing a multilayer printed wiring board, which comprises a step for forming an insulating layer on an internal circuit substrate and a step for forming a conductive layer on the insulating layer, wherein the insulating layer is formed by curing under heating of the epoxy resin composition as described in any of the above items (1) to (7), and the conductive layer is formed by metal-plating of the roughed surface generated by roughing treatment of the surface of the insulating layer.

(12) A process for producing a multilayer printed wiring board, which comprises a step for forming an insulating layer on an internal circuit substrate and a step for forming a conductive layer on the insulating layer, wherein the insulating layer is formed by laminating the adhesive film as described in the above item (8) on an internal circuit substrate, then curing under heating of the epoxy resin composition after or without removal of the support film, and then removing the support film when it is remaining, and the conductive layer is formed by metal-plating of the roughed surface generated by roughing treatment of the surface of the insulating layer.

(13) A process for producing a multilayer printed wiring board, which comprises a step for forming an insulating layer on an internal circuit substrate and a step for forming a conductive layer on the insulating layer, wherein the insulating layer is formed by laminating the prepreg as described in the above item (9) on an internal circuit substrate, and then curing under heating of the epoxy resin composition, and the conductive layer is formed by metal-plating of the roughed surface generated by roughing treatment of the surface of the insulating layer.

(14) A process as described in any of the above items (11) to (13), wherein the roughing treatment is carried out with a solution of alkaline permanganate.

(15) A semiconductor device, characterized in that a multilayer printed wiring board as described in the above item (10) is used.

By means of a specific epoxy resin composition comprising an epoxy resin, an active ester compound and a triazine-containing cresol novolac resin, it is possible to provide an epoxy resin composition, wherein the roughed surface generated from the surface of the cured product of said epoxy resin composition by a roughing treatment has high adhesion to a metal plated conductor, even though the roughness of the roughed surface is small, and the insulating layer has a low coefficient of linear expansion and a low dielectric loss tangent.

### DETAILED DESCRIPTION OF THE PREFERRED EMBODIMENTS

### (A) Epoxy Resin

The epoxy resin as a component (A) in the invention includes, but is not limited to, for example, bisphenol A-type epoxy resin, bisphenol F-type epoxy resin, phenol novolac-type epoxy resin, tert-butyl-catechol-type epoxy resin, naphthalene type epoxy resin, glycidylamine-type epoxy resin, cresol novolac type epoxy resin, biphenyl-type epoxy resin, linear aliphatic epoxy resin, alicyclic epoxy resin, heterocyclic epoxy resin, Spiro ring-containing epoxy resin, cyclohexanedimethanol-type epoxy resin, trimethylol-type epoxy resin, halogenated epoxy resin, and the like.

The epoxy resin may be used alone or in combination of two or more species, and contains two or more of epoxy groups in one molecule. It is preferable to use an epoxy resin in which at least 50% by weight thereof contains two or more of epoxy groups in one molecule. In another embodiment, it is more preferable to use an aromatic epoxy resin which has two or more of epoxy groups in one molecule and is liquid at a temperature of 20° C., and another aromatic epoxy resin which has three or more of epoxy groups in one molecule and is solid at a temperature of 20° C. According to the invention, the term aromatic epoxy resin means an epoxy resin which contains an aromatic ring structure in its molecule. The epoxy equivalent weight (g/eq) indicates the value which is obtained by dividing the mean molecular weight by the number of epoxy groups for one molecule. When the epoxy resin composition is used in a form of an adhesive film, the use of a liquid epoxy resin and a solid epoxy resin as epoxy resin allows forming a sufficiently flexible and easily handling adhesive film, resulting in improvement of the rupture strength of the cured product from the epoxy resin composition and of durability of the multilayer printed wiring boards.

In the combined use of a liquid epoxy resin and a solid epoxy resin as epoxy resin, the ratio of combination (liquid:solid) may preferably be in the range of 1:0.1 to 1:2 by weight, more preferably in the range of 1:0.5 to 1:1.5. Excessive amounts of the liquid epoxy resin over this range increases the adhesiveness of the epoxy resin composition, showing a tendency of decreasing the faculty for degassing prone to yielding a void during vacuum laminating, when used in a form of adhesive film. In addition, there is a tendency of decreasing the ease of the removal of a protective film or supporting film during vacuum laminating, and also decreasing the heat resistance after curing. Further, there is a tendency for the insufficient rupture strength to be obtained in the cured product from the epoxy resin composition. On the other hand, an excessive amount of the solid epoxy resin over such a range makes it difficult to obtain sufficient flexibility when it is used in a form of an adhesive film, resulting in a tendency in decreasing handling ability and yielding insufficient fluidity in laminating.

In the epoxy resin composition of the invention, the content of the epoxy resin is preferably 10 to 50% by weight for 100% by weight of the nonvolatile component in the epoxy resin composition, more preferably 12 to 40% by weight, and even more preferably 15 to 35% by weight. When the epoxy resin content is out of this range, there is a tendency of decreasing the curing property of the epoxy resin composition.

### (B) Active Ester Compounds

There is no particular limitation in the active ester compounds (B) according to the invention as far as they act as curing agents for epoxy resins and have an active ester, and they have preferably two or more of active ester groups in one molecule. In view of the heat resistance, etc., it is preferable to use an active ester compound which is prepared by reacting a carboxylic acid compound and/or thiocarboxylic acid compound with a hydroxy compound and/or thiol compound, and more preferably an active ester compound which is prepared by reacting a carboxylic acid compound with one or more of compounds selected from phenol compounds, naphthol compounds, and thiol compounds. Even more preferably, an aromatic compound having two or more active ester groups in one molecule is used which can be prepared by reacting a carboxylic acid compound with an aromatic compound having a phenolic hydroxy group. Particularly preferred are aromatic compounds which can be prepared by reacting a compound having at least two or more of carboxylic acids in one molecule with an aromatic compound having a phenolic hydroxy group and which have two or more of active ester groups in one molecule of the aromatic compound. In addition, they may be either straight chain or multibranched chain. The compound which has at least two or more carboxylic acids in one molecule acts to enhance compatibility with an epoxy resin when it contains an aliphatic chain, and further it works to increase heat resistance when it contains an aromatic ring. The carboxylic acid compound includes, specifically, benzoic acid, acetic acid, succinic acid, maleic acid, itaconic acid, phthalic acid, isophthalic acid, terephthalic acid, pyromellitic acid, and the like. In particular, in view of heat resistance, succinic acid, maleic acid, itaconic acid, phthalic acid, isophthalic acid, and terephthalic acid are preferred, and isophthalic acid and terephthalic acid are more preferable. The thiocarboxylic acid includes, specifically, thioacetic acid, thiobenzoic acid, and the like. The phenol compound or naphthol compound includes, specifically, hydroquinone, resorcinol, bisphenol A, bisphenol F, bisphenol S, phenolphthalein, methylated bisphenol A, methylated bisphenol F, methylated bisphenol S, phenol, o-cresol, m-cresol, p-cresol, catechol, α-naphthol, β-naphthol, 1,5-dihydroxynaphthalene, 1,6-dihydroxynaphthalene, 2,6-dihydroxynaphthalene, dihydroxybenzophenone, trihydroxybenzophenone, tetrahydroxybenzophenone, phloroglucinol, benzenetriol, dicyclopentadienyldiphenol, phenol novolac, and the like. In particular, in view of heat resistance and solubility, bisphenol A, bisphenol F, bisphenol S, methylated bisphenol A, methylated bisphenol F, methylated bisphenol S, catechol, α-naphthol, β-naphthol, 1,5-dihydroxynaphthalene, 1,6-dihydroxynaphthalene, 2,6-dihydroxynaphthalene, dihydroxybenzophenone, trihydroxybenzophenone, tetrahydroxybenzophenone, phloroglucinol, benzenetriol, dicyclopentadienyldiphenol, and phenol novolac are preferred; and catechol, 1,5-dihydroxynaphthalene, 1,6-dihydroxynaphthalene, 2,6-dihydroxynaphthalene, dihydroxybenzophenone, trihydroxybenzophenone, tetrahydroxybenzophenone, phloroglucinol, benzenetriol, dicyclopentadienyldiphenol, and phenol novolac are more preferred; further, 1,5-dihydroxynaphthalene, 1,6-dihydroxynaphthalene, 2,6-dihydroxynaphthalene, dihydroxybenzophenone, trihydroxybenzophenone, tetrahydroxybenzophenone, dicyclopentadienyldiphenol, and phenol novolac are more preferred; furthermore, dihydroxybenzophenone, trihydroxybenzophenone, tetrahydroxybenzophenone, dicyclopentadienyldiphenol, and phenol novolac are even more preferred; in particular, dicyclopentadienyldiphenol and phenol novolac are more preferred; and dicyclopentadienyldiphenol is particularly preferred. The thiol compound includes, specifically, benzenedithiol, triazinedithiol, and the like. The active ester compound may be used alone or in combination of two or more species.

The active ester compound containing the structure of dicyclopentadienyldiphenol includes, more specifically, those of the following formula (I):

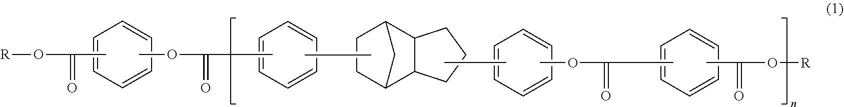

wherein R represents preferably phenyl group and naphthyl group, and more preferably naphthyl group; and n indicates preferably 0.5 to 2 on an average.

As for the active ester compounds, those disclosed in JP-A-2004-277460 may be employed or alternatively commercially available ones may be used. The commercially available active ester compound includes, specifically preferably, those having the dicyclopentadienyldiphenol structure, acetylated product of phenol novolac, and benzoylated product of phenol novolac, and more preferably, the compounds containing the dicyclopentadienyldiphenol structure. The compounds containing the dicyclopentadienyldiphenol structure includes EXB9451, EXB9460, and EXB9460S (Product of DIC Corporation). The acetylated product of phenol novolac includes DC808 (Product of Japan Epoxy Resins Co., Ltd.), and the benzoylated product of phenol novolac includes YLH1026 (Product of Japan Epoxy Resins Co., Ltd.).

There is no particular limitation in the process of producing the active ester compounds, which may be produced according to well-known processes; specifically, they may be produced by means of a condensation reaction of a carboxylic acid compound and/or thiocarboxylic acid compound with a hydroxy compound and/or thiol compound.

### (C) Triazine-Containing Cresol Novolac Resins

The triazine-containing cresol novolac resin (C) in the invention, which has both of the triazine skeleton and the cresol novolac structure in one molecule, works as a curing agent for epoxy resins, and in general it can be produced by the condensation reaction of cresol and a compound having a triazine ring such as melamine, benzoguanamine, and formaldehide. It includes, specifically, LA3018, LA3018-50P, EXB9808, EXB9829 (Product of DIC Corporation), and the like. The ratio by weight of the active ester compound to the triazine-containing cresol novolac resin is preferably from 1:0.05 to 1:1.5; more preferably from 1:0.05 to 1:1, even more preferably from 1:0.07 to 1:0.8, and particularly preferably from 1:0.1 to 1:0.6. An amount of the active ester compound smaller than this range shows a tendency of increasing the dielectric loss tangent of the cured product; and an amount of the triazine-containing cresol novolac resin smaller than this range has a tendency of increasing the coefficient of linear expansion for the cured product.

In this invention, the amounts of the active ester compound and the triazine-containing cresol novolac resin in the epoxy resin composition is preferably fixed so that the ratio of the epoxy group of the component (A) to the reactive groups (active ester group and active hydroxy group) of the components (B) and (C) in the epoxy resin composition is preferably from 1:0.3 to 1:1.5, more preferably from 1:0.4 to 1:1.3, even more preferably from 1:0.4 to 1:1.1, and particularly preferably from 1:0.4 to 1:0.8. In this connection, the epoxy group of the component (A) in the epoxy resin composition corresponds to the value obtained by summing up for all the epoxy resins the quotients obtained from the weight of the solid component of every epoxy resins divided by the epoxy equivalent weight; and the reactive groups of the components (B) and (C) correspond to the value obtained by summing up for all the curing agents the quotients obtained from the weight of the solid component of every curing agents divided by the equivalent of the reactive group. When the content of the curing agent is out of the appropriate range, there is a tendency for the heat resistance to become insufficient in the cured product of the epoxy resin composition.

The epoxy resin composition of the invention comprises a component (A), a component (B) and a component (C); the roughed surface generated from the surface of the cured product of the epoxy resin composition by a roughing treatment has a high adhesion to a metal plated conductor, even though the roughness of the roughed surface is small, and the dielectric loss tangent and the coefficient of linear expansion can be lowered.

The peeling strength of the cured product of the epoxy resin composition of the invention may be determined by means of the measurement method as described in “Measurement and Evaluation of the Strength for Peeling (peeling strength) in Plated Conductive Layer” mentioned below.

The upper limit of the peeling strength of the cured product of the epoxy resin composition in the invention is preferably 0.5 kgf/cm, more preferably 0.6 kgf/cm, even more preferably 0.7 kgf/cm, and particularly preferably 1.0 kgf/cm. The lower limit of the peeling strength of the cured product of the epoxy resin composition in the invention is preferably 0.3 kgf/cm, more preferably 0.35 kgf/cm, and even more preferably 0.4 kgf/cm.

The roughness of the cured product of the epoxy resin composition of the invention may be determined by means of the measurement method as described in “Measurement and Evaluation of the Arithmetic Mean Roughness (Ra) After Roughing Treatment” mentioned below.

The upper limit of the roughness of the cured product of the epoxy resin composition in the invention is preferably 220 nm, more preferably 200 nm, even more preferably 170 nm, and particularly preferably 140 nm. The lower limit of the roughness of the cured product of the epoxy resin composition in the invention is preferably 100 nm, more preferably 70 nm, and even more preferably 50 nm.

The dielectric loss tangent of the cured product of the epoxy resin composition of the invention may be determined by means of the measurement method as described in “Measurement and Evaluation of the Dielectric Loss Tangent” mentioned below.

The upper limit of the dielectric loss tangent of the cured product of the epoxy resin composition in the invention is preferably 0.010, more preferably 0.008, and even more preferably 0.006. The lower limit of the dielectric loss tangent of the cured product of the epoxy resin composition in the invention is preferably 0.003, more preferably 0.002, and even more preferably 0.001.

The average coefficient of linear expansion of the cured product of the epoxy resin composition of the invention may be determined by means of the measurement method as described in “Measurement and Evaluation of the Average Coefficient of Linear Expansion” mentioned below.

The upper limit of the average coefficient of linear expansion of the cured product of the epoxy resin composition in the invention is preferably 24 ppm, more preferably 22 ppm, even more preferably 20 ppm, and particularly preferably 17 ppm. The lower limit of the average coefficient of linear expansion of the cured product of the epoxy resin composition in the invention is preferably 14 ppm, more preferably 10 ppm, even more preferably 8 ppm, still more preferably 6 ppm, and particularly preferably 4 ppm.

In the present invention, an epoxy curing agent other than the active ester compound and the triazine-containing cresol novolac resin may be used together with the active ester compound and the triazine-containing cresol novolac resin. The epoxy curing agent other than the active ester compound and the triazine-containing cresol novolac resin includes phenolic curing agents such as TD2090, TD2131, KA1160, KA1165, LA7052, LA7054, LA7751, LA1356 (Product of DIC Corporation), MEH-7600, MEH-7851, MEH-8000H (Product of Meiwa Plastic Industries Ltd.), NHN, CBN, GPH-65, GPH-103 (Product of Nippon Kayaku Co., Ltd.), SN170, SN180, SN190, SN475, SN485, SN495, SN375, SN395 (Product of Tohto Kasei Co., Ltd.), and the like; benzoxazines such as F-a, P-d (Product of Shikoku Chemicals Corporation), HFB2006M (Product of Showa High polymer Co., Ltd.), and the like; and acid anhydrides such as methylhexahydrophthalic anhydride, methylnadic anhydride, hydrogenated methylnadic anhydride, and the like. The phenolic curing agents which are compounds having a phenolic hydroxy group are particularly preferred. These may be used alone or in combination of two or more species.

When the active ester compound and the triazine-containing cresol novolac resin are used together with another curing agent, the total % by weight of the active ester compound and the triazine-containing cresol novolac resin is preferably 10 to 100% by weight, more preferably 20 to 100% by weight, for 100% by weight of all of the epoxy curing agents (including the active ester compound and the triazine-containing cresol novolac resin) contained in the epoxy resin composition.

### (D) Inorganic Fillers

The epoxy resin composition of the present invention may further contain an inorganic filler in order to decrease the coefficient of linear expansion. The inorganic filler includes, for example, silica, alumina, barium sulfate, talc, clay, mica powder, aluminum hydroxide, magnesium hydroxide, calcium carbonate, magnesium carbonate, magnesium oxide, boron nitride, aluminum borate, barium titanate, strontium titanate, calcium titanate, magnesium titanate, bismuth titanate, titanium oxide, barium zirconate, calcium zirconate, and the like; in particular, silica such as amorphous silica, fused silica, hollow silica, crystalline silica, synthetic silica, etc., are particularly preferred. Silica may preferably be used in a spherical form. These may be used alone or in combination of two or more species.

The average particle size of the inorganic fillers is preferably 1 μm or smaller, more preferably 0.8 μm or smaller, and even more preferably 0.7 μm or smaller. When the average particle size is over 1 μm, there is a tendency for the peeling strength of the conductive layer formed by metal plating to decrease. In this connection, too small an average particle size of the inorganic fillers has a tendency to make the viscosity of varnish increase, resulting in decrease of handling ability, when the epoxy resin composition is used as resin varnish; thus, the average particle size is preferably 0.05 μm or greater. In order to improve the humidity resistance of the inorganic filler, it is preferable to use the filler whose surface is treated with a surface-treating agent such as epoxysilane-coupling agent, aminosilane-coupling agent, titanate-type coupling agent, and the like.

The average particle size of the above inorganic fillers can be determined by means of a laser diffraction scattering method based on the Mie scattering theory. Specifically, the particle size distribution of the inorganic filler is made on the basis of the volume using a laser diffraction apparatus for determining particle size distribution, from which the median diameter can be determined as an average particle size. As for a sample for measurement, preferably, the inorganic filler is dispersed in water by ultrasonication can be used. As for the laser diffraction apparatus for determining particle size distribution, the apparatus LA-500 (made by Horiba Ltd.) etc. may be used.

The content of the inorganic filler to be added is dependent on the characteristic property required for the epoxy resin composition, and is preferably 10 to 85% by weight, more preferably 20 to 80% by weight, even more preferably 40 to 80% by weight, and particularly preferably 60 to 80% by weight, for 100% by weight of the nonvolatile component contained in the epoxy resin composition. Too small a content of the inorganic filler has a tendency to increase the coefficient of linear expansion of the cured product; and too large a content has a tendency to make film formation difficult in the preparation of adhesive film or a tendency to make the cured product fragile.

### (E) Curing Accelerators

The epoxy resin composition of the present invention, additionally, may also contain a curing accelerator in order to, for example, adjust the curing time and the curing temperature. The curing accelerator includes, for example, organic phosphine compounds such as TPP, TPP-K, TPP-S, TPTP-S (Hokko Chemical Industry Co., Ltd.; trade name); imidazole compounds such as curezol 2MZ, 2E4MZ, C11Z, C11Z-CN, C11Z-CNS, C11Z-A, 2MZ-OK, 2MA-OK, 2PHZ (Shikoku Chemicals Corporation; trade name); amine adduct compounds such as Novacure (Asahi Kasei Corporation; trade name), Fujicure (Fuji Kasei Kogyo. Co., Ltd.; trade name); and amine compounds such as 1,8-diazabicyclo[5,4,0]undecene-7,4-dimethylaminopyridine, benzyldimethylamine, 2,4,6-tris(dimethylaminomethyl)phenol, and the like. These may be used alone or in combination of two or more species.

The content of the curing accelerator in the epoxy resin composition of the invention is preferably 0.01 to 5% by weight for 100% by weight of the nonvolatile components of the total of the epoxy resin and the epoxy curing agent contained in the epoxy resin composition.

### (F) Polymer Resin

In order to provide flexibility, the epoxy resin composition of the present invention may further contain one or more of polymer resins selected from polyvinylacetal resins, phenoxy resins, polyimide resins, polyamide imide resins, polyether imide resins, polysulfone resins, polyether sulfone resins, polyphenylene ether resins, polycarbonate resins, polyether ether ketone resins, and polyester resins. Particularly preferred are polyvinylacetal resins, phenoxy resins, polyimide resins, and polyester resins; and phenoxy resins are more preferred. These may be used alone or in combination of two or more species.

A specific example of the phenoxy resins includes those having a bisphenol A skeleton, e.g., 1256, 4250 produced by Japan Epoxy Resins Co., Ltd.; those having a bisphenol S skeleton, e.g., YX8100 produced by Japan Epoxy Resins Co., Ltd.; those having a bisphenol acetophenone skeleton, e.g., YX6954 produced by Japan Epoxy Resins Co., Ltd.; those having a bisphenol fluorenone skeleton, e.g., FX280, FX293 produced by Tohto Kasei Co., Ltd.; those having a biscresol fluorenone skeleton, e.g., YL7553 produced by Japan Epoxy Resins Co., Ltd.; those having a terpene skeleton, e.g., YL6794 produced by Japan Epoxy Resins Co., Ltd.; and those having a trimethylcyclohexane skeleton, e.g., YL7213, YL7290 produced by Japan Epoxy Resins Co., Ltd., and the like. These may be used alone or in combination of two or more species.

The weight-average molecular weight of the phenoxy resin is preferably in the range of 5000 to 70000, more preferably 10000 to 60000, and even more preferably 20000 to 50000. Too small a molecular weight has a tendency to make it difficult to obtain a conductive layer of sufficient peeling strength; and too large a molecular weight has a tendency to yield large roughness and to increase the coefficient of linear expansion.

The weight-average molecular weight can be determined by means of gel permeation chromatography (GPC) (in terms of polystyrene). The weight-average molecular weight by GPC can be determined by means of a measuring apparatus LC-9A/RID-6A (Shimadzu Corp.) using a column Shodex K-800P/K-804L (Showa Denko KK) and chloroform as mobile phase at a column temperature of 40° C., and calculated from a working curve of a standard polystyrene.

The content of the polymer resin in the epoxy resin composition of the invention is preferably 1 to 20% by weight, more preferably 1 to 10% by weight, for 100% by weight of the nonvolatile components in the epoxy resin composition. When the content is less than 1% by weight, sufficient flexibility cannot be obtained, and thereby handling ability tends to decline, and the conductive layer generated by metal plating tends to be insufficient in the peeling strength. When the content is over 20% by weight, there is a tendency for the fluidity to be insufficient in laminating and for the roughness to be excessive.

### (G) Rubber Particles

The epoxy resin composition of the present invention further may contain solid rubber particles in order to increase the mechanical strength of cured product, improve the workability with a drill, decrease the dielectric loss tangent, enhance the stress relaxation effect, and the like. The rubber particles used in the invention are not soluble in organic solvents used in preparation of the epoxy resin composition, are not compatible with the components such as epoxy resin contained in the resin composition, and exist in a dispersed state in varnish of the epoxy resin composition. The rubber particles may be used as a single species or in combination of two or more species. Such rubber particles in general may be prepared by enlarging the molecular weight of rubber component up to the level at which they do not dissolve themselves into organic solvents or resins to yield particles. The rubber particles include, for example, core shell-type rubber particles, bridged acrylonitrile butadiene rubber particles, bridged styrene butadiene rubber particles, acryl rubber particles, and the like. The core shell-type rubber particles, which have a core layer and a shell layer, include, for example, particles of two-layer structure in which the outer shell layer is glassy polymer and the inner core layer is rubber polymer, or particles of three-layer structure in which the outer shell layer is glassy polymer, the middle layer is rubber polymer, and the core layer is glassy polymer. The glassy polymer is, for example, composed of methyl methacrylate polymer, methyl acrylate polymer, styrene polymer, etc.; and the rubber polymer layer is, for example, composed of butyl acrylate polymer (butyl rubber), silicone rubber, polybutadiene, etc. Specific examples of the core shell-type rubber particles include Staphyloid AC3832, AC3816N (GANZ Chemical Co., Ltd.; trade name), Metablen W-5500 (Mitsubishi Rayon Co., Ltd.; trade name), and the like. A specific example of acrylonitrile butadiene rubber (NBR) particles includes XER-91 (average particle size: 0.5 μm; Product of JSR Corporation). A specific example of styrene butadiene rubber (SBR) particles includes XSK-500 (average particle size: 0.5 μm; Product of JSR Corporation). Specific examples of acryl rubber particles include Metablen W300A (average particle size: 0.1 μm) and W450A (average particle size: 0.5 μm) (Product of Mitsubishi Rayon Co., Ltd.).

The average particle size of the rubber particles to be added is preferably in the range of 0.005 to 1 μm, more preferably in the range of 0.2 to 0.6 μm. The average particle size of the rubber particles in the invention can be determined by means of a dynamic light scattering method. For example, rubber particles are dispersed homogeneously into an appropriate organic solvent by ultrasonication or the like, and the particle size distribution of the rubber particles is made on the basis of the weight using FPRA-1000 (Product of Otsuka Electronics Co., Ltd.), from which the median diameter can be determined as an average particle size.

When the rubber particles are blended into the epoxy resin composition, the content of the rubber particles is preferably 0.5 to 10% by weight, more preferably 1 to 4% by weight, for 100% by weight of the nonvolatile components in the epoxy resin composition.

### Other Thermosetting Resins.

The epoxy resin composition of the present invention, if required, further may be blended with a thermosetting resin such as cyanate resins, maleimide compounds, bisallylnadiimide compounds, vinylbenzyl resins, vinylbenzyl ether resins, and the like, to an extent in which the effect of the present invention is not negatively affected. The thermosetting resins may be used alone or in combination of two or more species. The cyanate resins include BADCY, LECY, BA230S70, PT15, PT30, PT60 (Product of Lonza Co., Ltd.); the maleimide resins include BMI1000, BMI2000, BMI3000, BMI4000, BMI5100 (Product of Daiwa Kasei Industry Co., Ltd.), BMI, BMI-70, BMI-80 (Product of KI Chemical Industry Co., Ltd.), ANILIX-MI (Product of Mitsui Fine Chemicals, Inc.); the bisallylnadiimide compounds include BANI-M, BANI-X (Product of Maruzen Petrochemical Co., Ltd.); the vinylbenzyl resins include V5000 (Product of Showa High polymer Co., Ltd.); and the vinylbenzyl ether resinsinclude V1000X, V1100X (Product of Showa High polymer Co., Ltd.).

### Flame Retardants.

The epoxy resin composition of the present invention, further, may be blended with a flame retardant to an extent in which the effect of the invention is not negatively affected. The flame retardants may be used alone or in combination of two or more species. The flame retardants include, for example, organophosphorous flame retardants, organic nitrogen-containing phosphorus compounds, nitrogen compounds, silicone flame retardants, metal hydroxide, and the like. The organophosphorous flame retardants include phosphine compounds such as HCA, HCA-HQ, HCA-NQ, etc. (Products of Sanko Co., Ltd.); phosphorus-containing benzoxazine compounds such as HFB-2006M (Product of Showa High polymer Co., Ltd.); phosphate ester compounds such as REOFOS 30, 50, 65, 90, 110, TPP, RPD, BAPP, CPD, TCP, TXP, TBP, TOP, KP140, TIBP (Products of Ajinomoto Fine Techno Co., Ltd.), PPQ (Product of Hokko Chemical Industry Co., Ltd.), P930 (Product of Clariant KK), PX200 (Product of Daihachi Chemical Industry Co., Ltd.), etc.; phosphorus-containing epoxy resins such as FX289, FX310 (Products of Tohto Kasei Co., Ltd.); and phosphorus-containing phenoxy resins such as ERF001 (Product of Tohto Kasei Co., Ltd.). The organic nitrogen-containing phosphorus compounds include phosphate estermide compounds such as SP670, SP703 (Products of Shikoku Chemicals Corporation), etc.; and phosphazene compounds such as SPB100, SPE100 (Products of Otsuka Chemical Co., Ltd.). The metal hydroxides include magnesium hydroxide such as UD65, UD650, UD653 (Products of Ube Material Industries, Ltd.), etc.; and aluminum hydroxide such as B-30, B-325, B-315, B-308, B-303, UFH-20 (Products of Tomoe Engineering, Co., Ltd.), etc.

### Resin Additives.

The epoxy resin composition of the present invention may optionally contain a variety of resin additives other than those mentioned above to an extent in which the effect of the invention is displayed. Such a resin additive includes, for example, organic fillers such as silicon powder, nylon powder, fluorine powder, etc.; thickeners such as Orben, Benton, etc.; defoaming agents or leveling agents of silicone type, fluorine type or high molecule type; adhesion supplements such as silane coupling agents of imidazole type, thiazole type, triazole type, etc.; and coloring agents such as phthalocyanine blue, phthalocyanine green, iodine green, disazoyellow, carbon black, and the like.

There is no particular limitation in the use of the resin compositions of the present invention, which can be applied to a wide variety of areas in which the resin compositions are needed, including adhesive films, insulating resin sheets such as prepregs, solder resists, underfill materials, die bonding materials, semi-conductor sealing materials, plugging resins, potting compounds for parts, and the like. In particular, the resin composition may be applied on a supporting film to form a layer of the resin composition to give an adhesive film for multilayer printed wiring boards, or used as prepreg for an insulating layer or layers between the layers of multilayer printed wiring boards by impregnating a sheet fiber base material comprising fiber with the resin composition. The resin compositions of the present invention may be applied onto a circuit substrate to form an insulating layer thereon, and in an industrial field they may be used generally in a form of adhesive film or prepreg in formation of an insulating layer.

### Adhesive Film.

The adhesive film of the present invention may be prepared according to methods well-known to persons of ordinary skill in the art, for example, by dissolving a resin composition in an organic solvent to give resin varnish, then applying the latter to a supporting film as a supporting structure, and drying the film under heating, blowing of hot air or the like to remove the organic solvent to form a layer of the resin composition.

The organic solvents include, for example, ketones such as acetone, methyl ethyl ketone, cyclohexanone, etc.; acetate esters such as ethyl acetate, butyl acetate, cellosolve acetate, propylene glycol monomethyl ether acetate, carbitol acetate, etc.; carbitols such as cellosolve, butylcarbitol, etc.; aromatic hydrocarbons such as toluene, xylene, etc.; and amide type solvents such as dimethylformamide, dimethylacetamide, N-methylpyrrolidone, etc. The organic solvent may be used in combination of two or more species.

There is no particular limitation on the drying condition, and the drying is made so that the content of organic solvent in the layer of resin composition is decreased to 10% or less by weight, and preferably to 5% or less by weight. The drying condition can be well established appropriately by means of a simple experiment. The drying condition is variable depending on the content of organic solvent in the varnish, and for example, a varnish containing 30 to 60% by weight of organic solvent may be dried at 50 to 150° C. for 3 to 10 minutes.

The thickness of the layer of resin composition formed in an adhesive film is usually made thicker than the conductive layer. Since the thickness of the conductive layer on the circuit substrate is usually in the range of 5 to 80 μm, the thickness of the layer of resin composition is preferably fixed in 10 to 100 μm. The layer of resin composition may be protected with a protective film as mentioned below. The protection with a protective film is effective in prevention of dust adherence or scratches on the surface of the resin composition.

As for the supporting film and protective film used in the present invention, polyolefins such as polyethylene, polypropylene, polyvinyl chloride, etc., polyesters such as polyethylene terephthalate (hereinafter, sometimes referred to as “PET”), polyethylene naphthalate, etc., polycarbonates, polyimides, and release paper or metal foil such as copper foil or aluminum foil are exemplified. The supporting film and protective film may optionally be subjected to a mat treatment, corona treatment, or release treatment.

The thickness of the supporting film is not particularly limited, and is preferably 10 to 150 μm, and more preferably 25 to 50 μm. The thickness of the protective film is not particularly limited neither, and is preferably 1 to 40 μm, and more preferably 10 to 30 μm. As described below, the supporting film used as a supporting structure in the process for producing adhesive film may be used as a protective film for protecting the surface of the layer of resin composition.

The supporting film of the invention is peeled off, after lamination on the circuit substrate, or after formation of the insulating layer by heat curing. By peeling off the supporting film after heat curing of the adhesive film, it is possible to prevent adhesion of dust or the like during the curing process and to improve the surface smoothness of the insulating layer after curing. When the film is peeled off after curing, the supporting film is preferably subjected to a release treatment in advance. In this situation, the layer of resin composition formed on the supporting film is preferably made so that the area of the layer is made smaller than that of the supporting film. In addition, the adhesive film may be winded in a roll, and preserved and stocked.

### Multilayer Printed Wiring Boards Using an Adhesive Film.

The following will explain a process for producing multilayer printed wiring boards using an adhesive film of the present invention. When the layer of the resin composition is protected by a protective film, the film is peeled off and the layer of the resin composition is laminated on one or both sides of the circuit substrate so that it has direct contact with the circuit substrate. The adhesive film of the invention may preferably be laminated on a circuit substrate under reduced pressure according to a vacuum laminating method. Lamination may be carried out in a batch system or in a successive manner with a roll. Alternatively, the adhesive film and the circuit substrate may be heated (pre-heated) if required before carrying out lamination.

The lamination may preferably be conducted under a condition of a crimp temperature (lamination temperature) of 70 to 140° C. and a crimp pressure of 1 to 11 kgf/cm² (9.8×10⁴-107.9×10⁴ N/m²), under reduced pressure of air pressure of 20 mmHg (26.7 hPa) or lower.

Vacuum lamination may be carried out using a commercially available vacuum laminator. Commercially available vacuum laminators include, for example, vacuum applicator (Product of Nichigo-Morton Co., Ltd.), vacuum pressure laminator (Product of Meiki Co., Ltd.), roll-type dry coater (Product of Hitachi Industries Co., Ltd.), and vacuum laminator (Product of Hitachi AIC Inc.).

The term inner layer circuit substrate in the present invention principally refers to the substrates such as glass epoxy, metal substrate, polyester substrate, polyimide substrate, BT resin substrate, heat cured polyphenylene ether substrate, etc., on one or both sides of which a patterned conductive layer (circuit) is formed. In producing a multilayer printed wiring board in which a conductive layer and an insulating layer are alternately layered and of which one or both sides are patterned to a conductive layer (circuit), there are the intermediate products on which an insulating layer and a conductive layer are expected to be additionally formed, and such intermediate products are also included within the inner layer circuit substrates of the invention. In the inner layer circuit substrates, it is preferable that the surface of the conductive circuit layer is subjected to roughing treatment such as darkening treatment in advance, in view of the adhesiveness of an insulating layer to an inner circuit substrate.

After an adhesive film is thus laminated on a circuit substrate, the supporting film is peeled off when necessary, and the laminated product may be subjected to heat curing to form an insulating layer on the circuit substrate. The heat curing condition may be chosen in the range of 150° C. to 220° C. for 20 minutes to 180 minutes, and preferably 160° C. to 200° C. for 30 to 120 minutes.

When the supporting film has not yet been peeled off before the curing, it is peeled off after the formation of the insulating layer. Thereafter, a hole or holes are made on the insulating layer formed on the circuit substrate to form (a) via hole(s) or through hole(s). Boring may be carried out, for example, according to a known method with a drill, laser, or plasma, or if required, by a combination of these techniques, and most commonly the boring is achieved by a laser such as carbon dioxide laser, YAG laser, etc.

Thereafter, a roughing treatment is conducted on the surface of the insulating layer. The roughing treatment in the present invention is preferably achieved by means of a wet roughing method using an oxidizing agent. The oxidizing agent includes permanganates (potassium permanganate, sodium permanganate, etc.), bichromates, ozone, hydrogen peroxide/sulfuric acid, nitric acid, and the like. It is preferred to carry out the roughing with an alkaline permanganate solution (e.g., an aqueous solution of sodium hydroxid containing potassium permanganate or sodium permanganate), which is an oxidizing agent widely used in the roughing of insulating layers in the production of multilayer printed wiring boards according to the build-up process.

The roughness of the roughed surface of the insulating layer after roughing treatment, in view of the formation of fine wiring, is preferably 220 nm or less as Ra value, more preferably 200 nm or less, even more preferably 170 nm or less, and particularly preferably 140 nm or less. The Ra value is one of the numerical values representing the roughness of surface, also referred to as the arithmetic mean roughness, and specifically determined by measuring and arithmetically averaging the absolute height value, which is variable within the measured area, from the average surface line. For example, the Ra value can be obtained from the numerical values measured in a VSI contact mode with a lens of 50 magnifications in a measurement range of 121 μm×92 μm, using an instrument WYKO NT3300 (Product of Veeco Instrument Inc.).

Thereafter, a conductive layer is formed on the surface of the resin composition layer on which uneven anchors have been generated by the roughing treatment by means of a non-electrolytic plating technique combined with an electrolytic plating technique. Alternatively, a plating resist may be formed in a pattern reverse to that of the conductive layer, from which a conductive layer may also be formed only by a non-electrolytic plating technique. In this connection, the peeling strength of the conductive layer can be improved and stabilized further by annealing treatment at 150 to 200° C. for 20 to 90 minutes after the formation of the conductive layer. The peeling strength of the conductive layer is preferably 0.5 kgf/cm or more, more preferably 0.6 kgf/cm or more.

The pattern processing and the circuit formation on the conductive layer may be carried out according to processes known to persons of ordinary skill in the art, for example, subtractive process, semi-additive process, etc.

### Prepreg.

The prepreg of the present invention may be produced by impregnating a sheet fiber base material comprising fiber with the resin composition of the present invention by means of a hot melt process or solvent process, followed by semi-curing under heating. That is, the prepreg is provided so that a sheet fiber base material comprising fiber is impregnated with the resin composition of the invention.

As for the sheet fiber base material comprising fiber, those usually used as fiber for prepreg, for example, glass cloth, aramid fiber, etc., may be used.

In the hot melt process, the resin is not dissolved in an organic solvent and is once coated on a coating paper which is easily peeled off from the resin, and it is then laminated on a sheet fiber base material or directly coated thereon with a dye coater to yield the prepreg. In the solvent process, in the same way as in the adhesive film, a sheet fiber base material is immersed in varnish of the resin dissolved in an organic solvent to impregnate the sheet fiber base material with the resin varnish, followed by drying.

### Multilayer Printed Wiring Boards Using Prepreg.

The following will explain a process for producing a multilayer printed wiring board of the present invention using the prepreg of the present invention. The prepreg of the present invention is layered as a single sheet or if required as multilayered sheets on a circuit substrate, and a metal plate is set to sandwich the substrate through a release film and press lamination is performed under a pressure and heating condition. The shape-forming is preferably carried out under pressure of 5 to 40 kgf/cm² (49×10⁴ to 392×10⁴ N/m²) at a temperature of 120 to 200° C. for 20 to 100 minutes. The wiring board may also be produced by laminating the prepreg on a circuit substrate by a vacuum laminating process in the same way as in the adhesive film, followed by heat curing. Thereafter, the cured prepreg surface is roughed with an oxidizing agent in the same way as mentioned above, and the conductive layer is formed by metal plating to produce a multilayer printed wiring board.

### Semiconductor Device.

Furthermore, semiconductor chips are mounted on the conducting parts of the multilayer printed wiring board of the present invention to produce a semiconductor device. The “conducting parts” means “the parts for conducting electric signals in the multilayer printed wiring boards”, which may be positioned on the surface or embedded parts therein. There is no particular limitation in the semiconductor chip as far as it is an electric circuit element made of semiconductor materials.

The method for mounting a semiconductor chip in producing the semiconductor device of the present invention, is not particularly limited, as far as the semiconductor chip works functionally and effectively, and specifically includes a wire bonding mounting method, a flip-chip mounting method, a method of mounting by bumpless build-up layer (BBUL), a method of mounting by anisotropic conductive film (ACF), a method of mounting by non-conductive film (NCF), and the like.

The “method of mounting by bumpless build-up layer (BBUL)” indicates “a method of mounting in which a semiconductor chip is buried directly in the concave of a multilayer printed wiring board, followed by connecting the semiconductor chip to the wiring on the printed wiring board”, which mounting method is further classified roughly into the following BBUL method 1) and BBUL method 2).

BBUL method 1): Mounting a semiconductor chip in the concave of the multilayer printed wiring board with an underfilling agent.

BBUL method 2): Mounting a semiconductor chip in the concave of the multilayer printed wiring board with an adhesive film or prepreg.

The BBUL method 1) comprises specifically the following steps:

Step 1): The conductive layers are removed from the both sides of the multilayer printed wiring board, in which through-holes are formed by a laser or mechanical drill.

Step 2): An adhesive tape is stuck on one side of the multilayer printed wiring board, and the base of the semiconductor chip is disposed in the through-hole so that it is fixed on the adhesive tape. In this state, it is preferable to place the semiconductor chip at a lower position than the height of the through-hole.

Step 3): An underfilling agent is poured and filled into the space between the through-hole and the semiconductor chip to fix the semiconductor chip to the through-hole.

Step 4): Then, the adhesive tape is peeled off to expose the base of the semiconductor chip.

Step 5): On the base side of the semiconductor chip is laminated the adhesive film or prepreg of the invention to cover the semiconductor chip.

Step 6): After curing of the adhesive film or prepreg, holes are made by a laser to expose the bonding pad being present on the base of the semiconductor chip, followed by achieving the above-mentioned roughing treatment, non-electrolytic plating, and electrolytic plating to connect the wiring. If required, an adhesive film or prepreg may further be laminated.

The BBUL method 2) specifically comprises the following steps.

Step 1): Photoresist films are formed on the conductive layers on both sides of the multilayer printed wiring board, and apertures are formed only on one side of the photoresist films by means of photolithography.

Step 2): The conductive layer exposed in the apertures is removed with an etching solution to expose the insulating layer, and thereafter, the resist films on both sides are removed.

Step 3): All of the exposed insulting layers are removed and boring is carried out with a laser or drill to form concaves. It is preferred to use a laser in which the laser energy can be adjusted so that the absorption index of the laser in copper decreases, and that in the insulating layer increases; in this situation, a carbon dioxide gas laser is more preferred. The use of such a laser allows removing only the insulating layer without penetrating the conductive layer on the opposite side of the aperture of the conductive layer.

Step 4): The base of the semiconductor chip is disposed at the concave so that it faces the aperture side, on which the adhesive film or prepreg of the invention is laminated from the aperture side to cover the semiconductor chip and fill up the space between the semiconductor chip and the concave. In this operation, it is preferred to put the semiconductor chip at the lower position than the height of the concave.

Step 5): After curing of the adhesive film or prepreg, holes are made by a laser to expose the bonding pad being present on the base of the semiconductor chip.

Step 6): The above-mentioned roughing treatment, non-electrolytic plating, and electrolytic plating are carried out to connect the wiring, and if required, an adhesive film or prepreg may further be laminated.

In view of miniaturization of semiconductor devices and reduction of transmission loss or in view of no influence of thermal history on the semiconductor chip because of using no solder or no strain produced in the future between the resin and solder, the method of mounting by bumpless build-up layer (BBUL) is preferably employed, and particularly, the BBUL methods 1) and 2) are more preferred, and the BBUL method 2) is even more preferred.

Other features of the invention will become apparent in the course of the following descriptions of exemplary embodiments which are given for illustration of the invention and are not intended to be limiting thereof.

### EXAMPLES

In the following examples, “part(s)” means “part(s) by weight”.

### Measurement Methods/Evaluation Methods.

First, a variety of measurement methods and evaluation methods will be explained.

### Preparation of Samples Used in Measurement of the Peeling Strength and Arithmetic Mean Roughness (Ra).

(1) Backing Treatment of Laminates

Both sides of a glass cloth base epoxy resin laminate of which both sides are plated with copper and in which an inner circuit is formed (the thickness of copper foil: 18 μm; thickness of substrate: 0.3 mm; RS715ES made of Matsushita Electric Works), were immersed into CZ8100 (MEC Company, Ltd.) to carry out roughing treatment of the copper surfaces.

(2) Lamination of Adhesive Films

The adhesive films prepared in Examples and Comparative Examples were laminated on both the sides of the laminate using a batch-type vacuum pressure laminator MVLP-500 (Meiki Co., Ltd.; trade name). Lamination was made by reducing air pressure to 13 hPa or lower for 30 seconds, followed by pressing under pressure of 0.74 MPa at 100° C. for 30 seconds.

(3) Curing of Resin Compositions

PET film was peeled off from the laminated adhesive film, and then the resin composition was cured in a curing condition at 180° C. for 30 minutes.

(4) Roughing Treatment

The laminate was immersed into a swelling solution, i.e., diethylene glycol monobutyl ether-containing Swelling Dip Seculigand P (Atotech Japan K.K.) at 60° C. for 5 minutes, then into Concentrate Compact P (aqueous solution of KMnO₄, 60 g/L; NaOH, 40 g/L) (Atotech Japan K.K.) as a roughing solution at 80° C. for 20 minutes, and finally into Reduction Solution Seculigand P (Atotech Japan K.K.) as a neutralizing solution at 40° C. for 5 minutes. The laminate after the roughing treatment was assessed for the arithmetic mean roughness (Ra) of the insulating layer.

(5) Metal Plating by a Semi-Additive Process

In order to form a circuit on the surface of insulating layer, the laminate was immersed into a PdCl₂-containing solution for non-electrolytic plating, and then into a non-electrolytic copper-plating solution. After annealing under heating at 150° C. for 30 minutes, an etching resist was formed, and after patterning by etching, electrolytic plating was performed with cupric sulfate to form a conductive layer of 30±5 μM in thickness. Thereafter, an annealing treatment was conducted at 180° C. for 60 minutes. For this laminate, the strength of peeling-off (peeling strength) of the plated conductive layer was determined.

### Measurement and Evaluation of the Strength of Peeling-Off (Peeling Strength) of the Plated Conductive Layer.

On the conductive layer of the laminate was made a cut of 10 mm in width and 100 mm in length; one end of the cut was peeled and picked up with a gripper, and peeled in the perpendicular direction up to 35 mm at a rate of 50 mm/minute at room temperature, at which stage the loading (kgf/cm) was measured. The peeling strength was evaluated as follows: [symbol] for the value being 0.7 or more, 0 for the value being less than 0.7 but 0.5 or more, Δ for the value being less than 0.5 but 0.3 or more, and X for the value being less than 0.3.

### Measurement and Evaluation of the Arithmetic Mean Roughness (Ra) After Roughing Treatment.

Using a non-contact type surface roughness tester (WYKO NT3300; Product of Veeco Instrument Inc.), the value (nm) of the arithmetic mean roughness (Ra) was obtained from the numerical values measured in a VSI contact mode with a lens of 50 magnifications in a measurement range of 121 μm×92 μm. The measurement was also achieved by obtaining the average value at 10 points. The results of the evaluation were indicated by O for the value of the arithmetic mean roughness being less than 180 nm, by Δ for the value being 180 nm or more but less than 230 nm, and by X for the value being 230 nm or more.

### Measurement and Evaluation of the Average Coefficient of Linear Expansion.

The adhesive films obtained in Examples 1 to 4 and Comparative Examples 1 to 4 were cured under heating at 190° C. for 90 minutes to yield sheet cured products. The cured products were cut into test pieces of 5 mm in width and 15 mm in length, which pieces were subjected to a thermomechanical analysis by means of a tensile test using the thermo mechanical analyzer made by Rigaku Co., Ltd. (Thermo Plus TMA8310). The test pieces were mounted on the above equipment, and tested continuously twice under a condition of 1 g loading at a temperature elevation rate of 5° C./minute. In the second test, the average coefficient of linear expansion (ppm) was calculated at temperatures of 25° C. to 150° C. The results of evaluation were indicated by [symbol] for the value of the coefficient of linear expansion being less than 18 ppm, by O for the value being 18 ppm or more but less than 25 ppm, and by X for the value being 25 ppm or more.

### Measurement and Evaluation of Dielectric Loss Tangent.

The adhesive films obtained in Examples 1 to 4 and Comparative Examples 1 to 4 were cured under heating at 190° C. for 90 minutes to yield sheet cured products. The cured products were cut into test pieces of 2 mm in width and 80 mm in length, for which pieces the dielectric loss tangent (tan δ) was determined by means of a cavity resonance method at a measurement frequency of 5.8 GHz using a permittivity measuring apparatus CP521 based on the cavity resonator perturbation (Product of Kantoh Electronics Application and Development Inc.) and a Network Analyzer E8362B (Product of Agilent Technologies Inc.). The measurement was made for two test pieces to calculate the average values. The results of evaluation were indicated by [symbol] for the value of the dielectric loss tangent being less than 0.007, by O for the value being 0.007 or more but less than 0.009, by Δ for the value being 0.009 or more but less than 0.011, and by X for the value being 0.011 or more.

### Example 1

Liquid bisphenol type A epoxy resin (epoxy equivalent weight 180, Product of Japan Epoxy Resins Co.; jER828EL)(15 parts) and biphenyl-type epoxy resin (epoxy equivalent weight 291, Product of Nippon Kayaku Co., Ltd.; NC3000H)(15 parts) were dissolved with heating in 15 parts of methyl ethyl ketone (hereinafter abbreviated to MEK) and 15 parts of cyclohexanone while stirring. There were added 20 parts of an active ester compound (Product of DIC Corporation; “EXB9460S-65T”, active ester equivalent 223, a toluene solution containing 65% solid portion), 6 parts of triazine-containing cresol novolac resin (Product of DIC Corporation; “LA3018-50P”, phenol equivalent 151, a 2-methoxypropanol solution containing 50% solid portion), 0.05 parts of curing accelerator (Product of Koei Chemical Co., Ltd.; “4-dimethylaminopyridine”), 88 parts of spherical silica (average particle size 0.5 aminosilane-treated “SO-C2”; Product of Admatechs Co., Ltd.), and 7 parts of phenoxy resin (YL6954BH30; MEK and cyclohexanone (1:1) solution containing 30% by weight non-volatile material; weight average molecular weight 40000), and the mixture was homogeneously dispersed with a high-speed mixer to produce a resin varnish (65% by weight of silica; the ratio of the epoxy group in Component (A) to the reactive groups in Components (B) and (C), being 1:0.57; and the ratio of the active ester compound to the triazine-containing cresol novolac resin, being 1:0.23).

The resulting resin varnish was then applied on a polyethylene terephthalate sheet (38 μm in thickness; hereinafter abbreviated to “PET”) with a dye coater and dried at 80-120° C. (average: 100° C.) for 6 minutes (residual solvent: about 2% by weight) so that the resin thickness became 40 μm after drying. The product was rolled up in a roll while a polypropylene film of 15 μm in thickness was adhered on the surface of the resin composition. The rolled adhesive film was slit into 507 mm in width to yield a sheet adhesive film of 507×336 mm in size.

### Example 2

In place of 88 parts of spherical silica in Example 1, 140 parts of spherical silica was added, and otherwise treated in the same manner as in Example 1 to yield resin varnish (74% by weight of silica; the ratio of the epoxy group in Component (A) to the reactive groups in Components (B) and (C), being 1:0.57; and the ratio of the active ester compound to the triazine-containing cresol novolac resin, being 1:0.23). Thereafter, an adhesive film was prepared in the same manner as in Example 1.

### Example 3

In place of 20 parts of the active ester compound and 6 parts of the triazine-containing cresol novolac resin used in Example 1, 15 parts of the active ester compound and 10 parts of the triazine-containing cresol novolac resin were added, and otherwise treated in the same manner as in Example 1 to yield resin varnish (65% by weight of silica; the ratio of the epoxy group in Component (A) to the reactive groups in Components (B) and (C), being 1:0.57; and the ratio of the active ester compound to the triazine-containing cresol novolac resin, being 1:0.51). Thereafter, an adhesive film was prepared in the same manner as in Example 1.

### Example 4

In the same manner as in Example 1, resin varnish (65% by weight of silica; the ratio of the epoxy group in Component (A) to the reactive groups in Components (B) and (C), being 1:0.57; and the ratio of the active ester compound to the triazine-containing cresol novolac resin, being 1:0.23) was prepared except that 2 parts of rubber particles (Product of GANZ Chemical Co., Ltd.: IM401-4-14; core shell type rubber particles of which the core is polybutadiene and the shell is copolymer of styrene and divinylbenzene) was added. Thereafter, an adhesive film was prepared in the same manner as in Example 1.

### Comparative Example 1

In place of 6 parts of the triazine-containing cresol novolac resin and 0.05 part of the curing accelerator used in Example 1, 3 parts of cresol novolac resin (Product of DIC Corporation; “KA 1165”, phenol equivalent 119) and 0.1 part of curing accelerator were added, and otherwise treated in the same manner as in Example 1 to yield resin varnish (65% by weight of silica; the ratio of the epoxy group in Component (A) to the reactive groups in Components (B) and (C), being 1:0.61; and the ratio of the active ester compound to the cresol novolac resin, being 1:0.23). Thereafter, an adhesive film was prepared in the same manner as in Example 1.

### Comparative Example 2

In place of 6 parts of the triazine-containing cresol novolac resin used in Example 1, 5 parts of triazine-containing phenol novolac resin (Product of DIC Corporation; “LA7054”, phenol equivalent 125, a MEK solution containing 60% solid portion) was added, and otherwise treated in the same manner as in Example 1 to yield resin varnish (65% by weight of silica; the ratio of the epoxy group in Component (A) to the reactive groups in Components (B) and (C), being 1:0.60; and the ratio of the active ester compound to the triazine-containing phenol novolac resin, being 1:0.23). Thereafter, an adhesive film was prepared in the same manner as in Example 1.

### Comparative Example 3

In place of 88 parts of spherical silica and 20 parts of the active ester compound used in Example 1, 100 parts of spherical silica and 36 parts of the active ester compound were added, and otherwise treated in the same manner as in Example 1 to yield resin varnish (64% by weight of silica; and the ratio of the epoxy group in Component (A) to the reactive groups in Components (B) and (C), being 1:0.77). Thereafter, an adhesive film was prepared in the same manner as in Example 1.

### Comparative Example 4

In place of 88 parts of spherical silica, 20 parts of the active ester compound and 6 parts of the triazine-containing cresol novolac resin, 80 parts of spherical silica and 23 parts of the triazine-containing cresol novolac resin were added, and otherwise treated in the same manner as in Example 1 to yield resin varnish (65% by weight of silica; and the ratio of the epoxy group in Component (A) to the reactive groups in Components (B) and (C), being 1:0.56). Thereafter, an adhesive film was prepared in the same manner as in Example 1.

The results are shown in Table 1.

### Table 1.

TABLE 1

| | | Ex 1 | Ex 2 | Ex 3 | Ex 4 | Com. Ex 1 | Com. Ex 2 | Com. Ex 3 | Com. Ex 4 |
|---|---|---|---|---|---|---|---|---|---|
| jER828EL | Liq. bisphenol A type epoxy resin | 15 | 15 | 15 | 15 | 15 | 15 | 15 | 15 |
| NC3000H | Biphenyl type epoxy resin | 15 | 15 | 15 | 15 | 15 | 15 | 15 | 15 |
| MEK | Solvent | 15 | 15 | 15 | 15 | 15 | 15 | 15 | 15 |
| Cyclohexane | Solvent | 15 | 15 | 15 | 15 | 15 | 15 | 15 | 15 |
| SO—C2 | Silica | 88 | 140 | 88 | 88 | 88 | 88 | 100 | 80 |
| YL6954BH30 | Phenoxy resin | 7 | 7 | 7 | 7 | 7 | 7 | 7 | 7 |
| EXB9460S-65T | Active ester compound | 20 | 20 | 15 | 20 | 20 | 20 | 36 | |
| LA3018-50P | Triazine-contg. cresol novolac resin | 6 | 6 | 10 | 6 | | | | 23 |
| KA1165 | Cresol novolac resin | | | | | 3 | | | |
| LA7054 | Triazine-contg. phenol novolac resin | | | | | | 5 | | |
| IM401-4-14 | Rubber particles | | | | 2 | | | | |
| DMAP | 4-Dimethylamino-pyridine | 0.05 | 0.05 | 0.05 | 0.05 | 0.1 | 0.05 | 0.05 | 0.05 |

| | | | | | | | | |
|---|---|---|---|---|---|---|---|---|
| Peeling strength (kgf/cm) | ◯ | ◯ | ◯ | [symbol] | X | Δ | X | Δ |
| | 0.6 | 0.5 | 0.5 | 0.7 | 0.2 | 0.4 | 0.1 | 0.4 |
| Arithmetic mean roughness (nm) | ◯ | ◯ | ◯ | ◯ | Δ | X | ◯ | X |
| | 135 | 170 | 120 | 145 | 200 | 240 | 100 | 450 |
| Average coefficient of linear expansion (ppm) | ◯ | [symbol] | ◯ | ◯ | X | X | X | ◯ |
| | 23 | 15 | 22 | 24 | 36 | 26 | 32 | 20 |
| Dielectric loss tangent | ◯ | [symbol] | Δ | ◯ | X | Δ | ◯ | X |
| | 0.008 | 0.006 | 0.010 | 0.008 | 0.011 | 0.009 | 0.008 | 0.012 |

As shown clearly in Table 1, the plated conductive layer in a sample for evaluation in each of Examples 1-4 has a high peeling strength and further shows a low average coefficient of linear expansion and low dielectric loss tangent, even though it has a low arithmetic mean roughness. On the other hand, Comparative Example 1 in which a cresol novolac resin was used in place of the triazine-containing cresol novolac resin, shows a relatively high arithmetic mean roughness and a low peeling strength with a high average coefficient of linear expansion and high dielectric loss tangent. In Comparative Example 2 in which a triazine-containing phenol novolac resin was used in place of the triazine-containing cresol novolac resin, the dielectric loss tangent was low, but the arithmetic mean roughness and the average coefficient of linear expansion became high. Further, in Comparative Example 3 in which an active ester compound was used in place of the triazine-containing cresol novolac resin, the average coefficient of linear expansion was increased, and the peeling strength was decreased. In Comparative Example 4 in which no active ester compound was contained and a triazine-containing cresol novolac resin was used instead, the dielectric loss tangent and the arithmetic mean roughness were increased.

### INDUSTRIAL APPLICABILITY

It becomes possible to provide an epoxy resin composition, wherein the roughed surface generated from the surface of the cured product of the epoxy resin composition by roughing treatment has a high adhesion strength to a metal plated conductor, even though the roughness of the roughed surface is relatively small, and an insulating layer has a low coefficient of linear expansion and a low dielectric loss tangent. Thus, said epoxy resin composition provides adhesive films, prepreg, multilayer printed wiring boards, and semiconductor devices. In addition, it becomes possible to provide products comprising the above, including electrical products such as computers, cellular phones, digital cameras, televisions, etc., and vehicles such as motorbikes, motorcars, electric cars, ships, airplanes, etc.

Where a numerical limit or range is stated herein, the endpoints are included. Also, all values and subranges within a numerical limit or range are specifically included as if explicitly written out.

Obviously, numerous modifications and variations of the present invention are possible in light of the above teachings. It is therefore to be understood that, within the scope of the appended claims, the invention may be practiced otherwise than as specifically described herein.

All patents and other references mentioned above are incorporated in full herein by this reference, the same as if set forth at length.

1. An epoxy resin composition, which comprises”
(A) at least one epoxy resin (A);
(B) at least one active ester compound; and
(C) at least one triazine-containing cresol novolac resin.

2. An epoxy resin composition as claimed in claim 1, wherein the ratio of epoxy groups of the said component (A) to reactive groups of said components (B) and (C) is from 1:0.3 to 1:1.5, and the ratio by weight of nonvolatile components in said component (B) to said component (C) is from 1:0.05 to 1:1.5.

3. An epoxy resin composition as claimed in claim 1, which further comprises:
(D) at least one inorganic filler.

4. An epoxy resin composition as claimed in claim 1, which further comprises:
(E) at least one curing accelerator.

5. An epoxy resin composition as claimed in claim 1, which further comprises:
(F) one or more species of polymer resin selected from the group consisting of polyvinyl acetal resin, phenoxy resin, polyimide resin, polyamide-imide resin, polyether imide resin, polysulfone resin, polyether sulfone resin, polyphenylene ether resin, polycarbonate resin, polyether ether ketone resin, polyester resin, and mixtures thereof.

6. An epoxy resin composition as claimed in claim 1, which further comprises:
(G) rubber particles.

7. A cured layer of an epoxy resin composition as claimed in claim 1

8. A cured layer as claimed in claim 1, which has a surface with an arithmetic mean roughness of 50 nm to 220 nm and which exhibits a dielectric loss tangent of 0.001 to 0.010 and an average coefficient of linear expansion of 4 ppm to 24 ppm.

9. A cured layer as claimed in claim 1, which further comprises a layer of another material on at least one surface thereof and which exhibits a peeling strength between said cured layer and said layer of said another material of 0.3 kgf/cm to 1.0 kgf/cm.

10. An adhesive film, which comprises an epoxy resin composition as claimed in claim 1 layered on a support film.

11. An adhesive film, which comprises an epoxy resin composition as claimed in claim 2 layered on a support film.

12. An adhesive film, which comprises an epoxy resin composition as claimed in claim 3 layered on a support film.

13. A prepreg, which comprises a sheet fiber base material impregnated with an epoxy resin composition as claimed in claim 1.

14. A prepreg, which comprises a sheet fiber base material impregnated with an epoxy resin composition as claimed in claim 2.

15. A prepreg, which comprises a sheet fiber base material impregnated with an epoxy resin composition as claimed in claim 3.

16. A multilayer printed wiring board, which comprises an insulating layer which is a cured layer of an epoxy resin composition as claimed in claim 1.

17. A process for producing a multilayer printed wiring board, which comprises:
(a) forming an insulating layer on an internal circuit substrate; and
(b) forming a conductive layer on said insulating layer,
wherein said insulating layer is formed by curing with heating an epoxy resin composition as claimed in claim 1, and said conductive layer is formed by metal-plating on a roughed surface generated by a roughing treatment of a surface of said insulating layer.

18. A process for producing a multilayer printed wiring board, which comprises:
(a) forming an insulating layer on an internal circuit substrate; and
(b) forming a conductive layer on said insulating layer,
wherein said insulating layer is formed by:
(i) laminating an adhesive film as claimed in claim 10 on an internal circuit substrate;
(ii) curing said epoxy resin composition of said adhesive film with heating after or without removal of said support film; and
(iii) removing said support film when it is remaining, and
wherein said conductive layer is formed by metal-plating of a roughed surface generated by a roughing treatment of the surface of said insulating layer.

19. A process for producing a multilayer printed wiring board, which comprises:
(a) forming an insulating layer on an internal circuit substrate;
(b) forming a conductive layer on said insulating layer,
wherein said insulating layer is formed by:
(i) laminating a prepreg as claimed in claim 13 on an internal circuit substrate;
(ii) curing said epoxy resin composition of said prepreg with heating, and
wherein said conductive layer is formed by metal-plating of a roughed surface generated by a roughing treatment of a surface of said insulating layer.

20. A semiconductor device, which comprises a multilayer printed wiring board as claimed in claim 16.
